(19) United States
(12) Patent Application Publication
(10) Pub. No.: US 2021/0355573 A1
(43) Pub. Date: Nov. 18, 2021

(54) Mask Assembly and Method for Manufacturing a Film Layer

(71) Applicant: Wuhan China Star Optoelectronics Semiconductor Display Technology Co., LTD., Wuhan, Hubei (CN)

(72) Inventor: Sisi ZHOU, Wuhan, Hubei (CN)

(73) Assignee: Wuhan China Star Optoelectronics Semiconductor Display Technology Co., LTD., Wuhan, Hubei (CN)

(21) Appl. No.: 16/485,442

(22) PCT Filed: Feb. 14, 2019
(86) PCT No.: PCT/CN2019/075030

§ 371 Date: Aug. 12, 2019

(30) Foreign Application Priority Data
Dec. 15, 2018 (CN) 201811537529.1

(51) Int. Cl. C23C 14/04; C23C 14/24

(52) U.S. Cl. CPC C23C 14/042; C23C 14/24

(57) ABSTRACT

A mask assembly used for forming a film layer of a display area is provided. The display area includes at least one transparent region and at least one non-transparent region. The mask assembly includes at least two mask plates, each mask plate having an opening area. The opening areas of the two mask plates are complementary in shape, and the at least one non-transparent region of the display area is formed by the opening areas after combining the opening areas together. The shapes of the opening areas of the two mask plates have an overlapped part.

### FIELD OF INVENTION

The present invention relates to a field of display panel, and particularly relates to a mask assembly and method for manufacturing film layers using the mask assembly and display panel using the film layers.

### BACKGROUND OF INVENTION

In recent years, in order to increase the screen ratio of electronic products, the non-display area on the display panel has been reduced to be smaller and smaller. For example, in the mobile phone display 1 as shown in FIG. 1A and FIG. 1B, there is a display area 11 and a bonding area 12. In order to minimize the area of the non-display area, a notch (shaped area) 13 is provided in the upper end of the display area 11 as shown in FIG. 1A and FIG. 1B for accommodating a front-facing camera and a receiver of the mobile phone in the notch 13.

### Technical Problem

However, setting the notch in the display area affects the regularity and integrity of the display area, so full-screen display of the electronic device cannot be achieved.

Therefore, there is a need for a new display panel structure to increase the screen ratio of the electronic product, thereby achieving full-screen display.

### Technical Solution

The purpose of the present invention is to provide a mask assembly. Through a plurality of mask plates and an opening area design of each mask, a film layer can be formed in a display area which comprises at least one transparent region, so that the film layers are formed only in an area of the display area that does not include the transparent area to increase the screen ratio.

In order to achieve the above object, the present invention provides a mask assembly, used for forming a film layer having a display area which comprises at least one transparent region and at least one non-transparent region. The at least one transparent region is a closed graph, and a boundary of the at least one transparent region is independent from a boundary of the display area. The mask assembly includes two mask plates, each mask plate having an opening area. The opening areas of the two mask plates are complementary in shape, and the at least one non-transparent region of the display area is formed by the opening areas after combining the opening areas together. The shapes of the opening areas of the two mask plates have an overlapped part. A total area of the opening areas of the two mask plates is larger than an area of the at least one non-transparent region of the display area.

The invention also provides a mask assembly, which is used for forming a film layer having a display area. The display area includes at least one transparent region and at least one non-transparent region. The mask assembly includes two mask plates, each mask plate having an opening area. The opening areas of the two mask plates are complementary in shape, and the at least one non-transparent region of the display area is formed by the two opening areas after combining the two opening areas together The shapes of the opening areas of the mask plates have an overlapped part.

In one embodiment, the at least one transparent region is a closed graph, and a boundary of the transparent area is independent from a boundary of the display area.

In one embodiment, a total area of the opening areas of the mask plates is larger than an area of the at least one non-transparent region of the display area.

In one embodiment, the mask assembly comprises two mask plates.

The invention also provides a method for manufacturing a film layer. The method uses the above mask assembly, wherein a same material is evaporated through each of the mask plates functioning as a shield layer to form an evaporation coating film layer having the display area with the at least one transparent region.

In one embodiment, the evaporation coating film layer is a cathode layer or a thin film encapsulation functional layer.

The invention also provides a display panel, which has a display area and a transparent region formed in the display area. The transparent region is a closed graph, and a boundary of the transparent area is independent from a boundary of the display area.

The invention also provides a method for manufacturing a display panel. The method includes using the above mask assembly, wherein a same material is evaporated through each of the mask plates functioning as a shield layer to form an evaporation coating film layer having the display area with the at least one transparent region; the evaporation coating film layer is a cathode layer or a thin film encapsulation functional layer.

### Beneficial Effect

In the present invention, through the structural design of the plurality of mask plates, the purpose of vaporizing the functional layer on the display area of the display panel and not on the transparent region by using the same material in multiple steps can be achieved. Thereby, the screen ratio of the display panel is further improved.

### DESCRIPTION OF DRAWINGS

In order to more clearly illustrate the technical solutions in the embodiments of the present invention, the drawings used in the description of the embodiments will be briefly described below. It is obvious that the drawings in the following description are only some embodiments of the present invention. Other drawings can also be obtained from those skilled in the art based on these drawings without paying any creative effort.

FIG. 1A and FIG. 1B are schematic views showing a conventional mobile phone display screen;

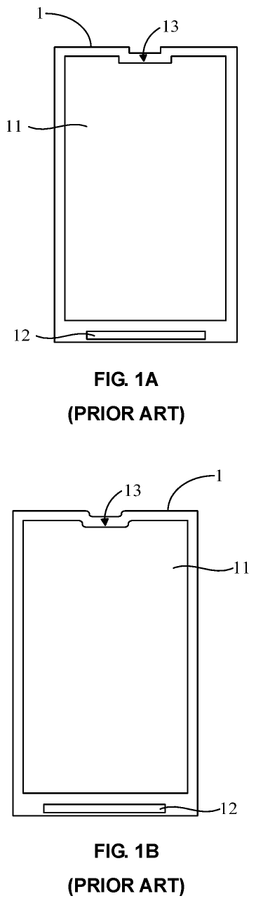

FIG. 2 is a schematic view of a display panel according to an embodiment of the present invention;

FIG. 3A and FIG. 3B are schematic views showing a mask assembly according to an embodiment of the present invention;

FIG. 4A and FIG. 4B are schematic views showing a mask assembly according to another embodiment of the present invention;

FIG. 5A and FIG. 5B are schematic views showing a mask assembly according to still another embodiment of the present invention;

FIG. 6A and FIG. 6B are schematic views showing a film layer manufacturing process according to an embodiment of the present invention.

### DETAILED DESCRIPTION OF PREFERRED EMBODIMENTS

The embodiments of the present invention are described in detail below, and the examples of the embodiments are illustrated in the drawings, wherein the same or similar reference numerals indicate the same or similar elements or elements having the same or similar functions. The embodiments described below with reference to the drawings are intended to be illustrative of the invention and are not to be construed as limiting.

In the present invention, the first feature “on” or “under” the second feature may include direct contact of the first and second features, and may also be included that the first and second features are not in direct contact but are contacted by additional features between them. It is not in direct contact but through additional features between them. Moreover, the first feature “above”, “over” and “on top of” the second feature includes the first feature directly above and oblique upper the second feature, or merely indicating that the first feature level is higher than the second feature. The first feature “below”, “under” and “underside” the second feature includes the first feature directly below and oblique below the second feature, or merely the first feature level being less than the second feature.

The following disclosure provides many different embodiments or examples for implementing different structures of the present invention. In order to simplify the disclosure of the present invention, the components and arrangements of the specific examples are described below. Of course, they are merely examples and are not intended to limit the invention. In addition, the present invention may be repeated with reference to the numerals and/or reference numerals in the various examples, which are for the purpose of simplicity and clarity, and do not indicate the discussion of the relationship between the various embodiments and/or settings. Moreover, the present invention provides examples of various specific processes and materials, however, those skilled in the art will be aware of the invention of other processes and/or the use of other materials.

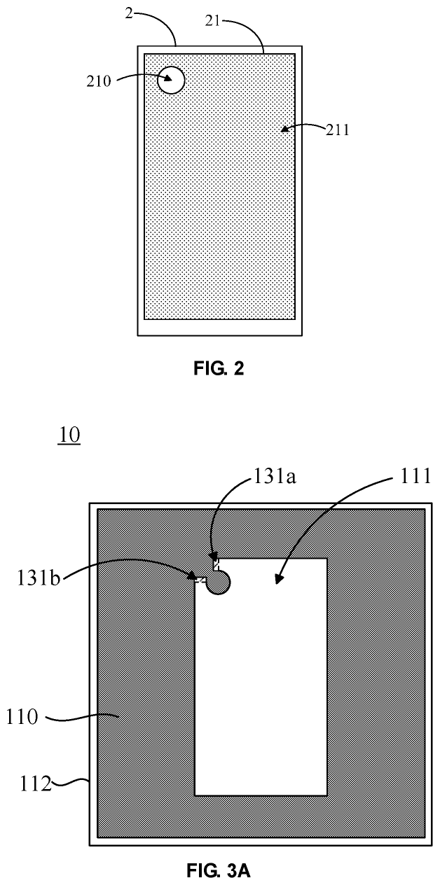

For achieving full-screen display, a display panel as shown in FIG. 2 is provided in this embodiment. As show in FIG. 2, there is a display area 21 in the display panel 2, and a transparent region 210 is formed in the display area 21 for setting a front-facing camera. As show in FIG. 2, the at least one transparent region 210 is a closed graph, and a boundary of the transparent region 210 is independent from a boundary of the display area 21, so that the display area 21 is divided into a transparent region 210 and a non-transparent region 211. The transparent region 210 may be circular or rectangular or irregular. The circular transparent region 210 shown in FIG. 2 is only used as an example and is not used to limit the shape of the transparent region 210. Further, the transparent region 210 may be located at any position within the display area 21, and is not limited to the upper left corner position as shown in FIG. 2. Furthermore, multiple ones of the transparent region 210 may be included in the display area 21.

Hereinafter, the display panel 2 shown in FIG. 2 is taken as an example, in which the mask assembly provided by the present invention and the use of the mask assembly to obtain a film layer forming a display area of a sealed and border-independent transparent region are explained in detail. It will be understood by those skilled in the art that the shapes of the display area 21 and the transparent region 210 are not limited by the shapes shown in the drawings, and the position of the transparent region 210 in the display area 21 is also not limited by the position shown in the drawings.

Moreover, those skilled in the art can understand that the position and shape of the opening area of the mask assembly in the present invention are different according to the shape and relative position of the display area 21 and the transparent region 210. The shape of the mask assembly shown in the drawings is only used as an example and is not used to limit the mask assembly described herein.

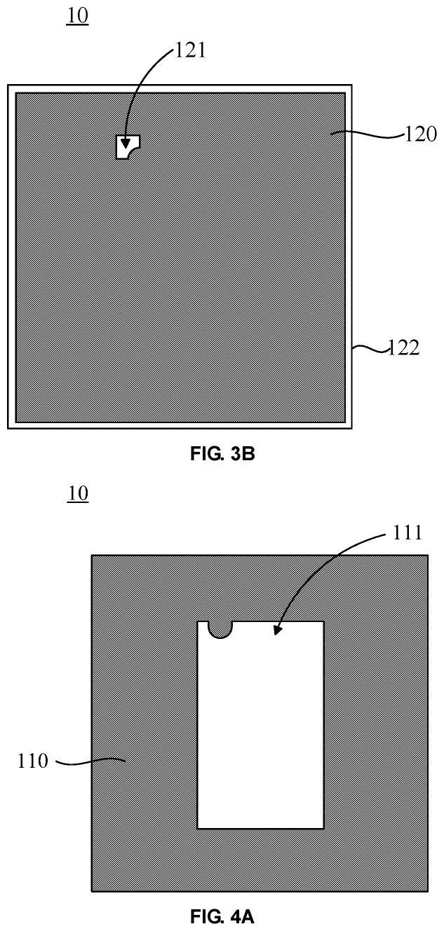

As show in FIG. 3A and FIG. 3B, a mask assembly 10 is provided in this embodiment. The mask assembly 10 includes a first mask plate 110 as shown in FIG. 3A and a second mask plate 120 as shown in FIG. 3B. The first mask plate 110 has a first opening area 111, and the second mask plate 120 has a second opening area 112. The first and second opening areas 111, 121 of the first mask plate 110 and the second mask plate 120 are complementary in shape, and the non-transparent region 211 of the display area 21 is formed by combining the first opening area 111 and the second opening area 121 together. A sum of the areas of the first and second opening areas 111, 121 is actually larger than an area of the non-transparent region 211 which is equal to a difference of the areas respectively of the display area 21 and the transparent region 210.

That is, the vertical projections of the first opening area 111 and the second opening area 121 are complementary, and may constitute the non-transparent region 211 as shown in FIG. 2 (i.e., the remaining area of the display area 21 by removing the transparent region 210). Moreover, the vertical projections of the first opening area 111 and the second opening area 121 have overlapping portions (131a, 131b), so that a complete and continuous film layer can be obtained in the film layer manufacturing process which will be described in detail below.

It can be known by those skilled in the art that the overlapping portions (131a, 131b) may be located in the first open area 111 as shown in FIG. 3A, and may also be located in the second open area 121 as shown in FIG. 3B. Or each of the first open area 111 and the second open area 121 has an overlapping portion. Of course, considering the thickness of the display panel, the flatness of the film, etc., it is better that the area of the overlapping portions (131a, 131b) is as small as possible.

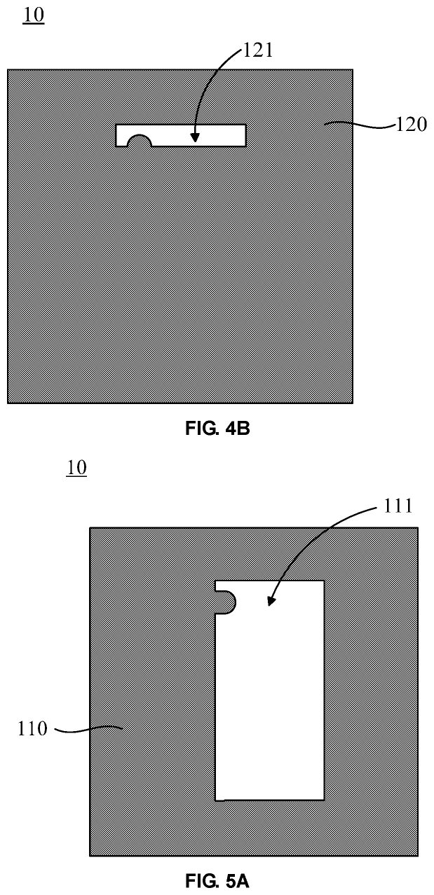

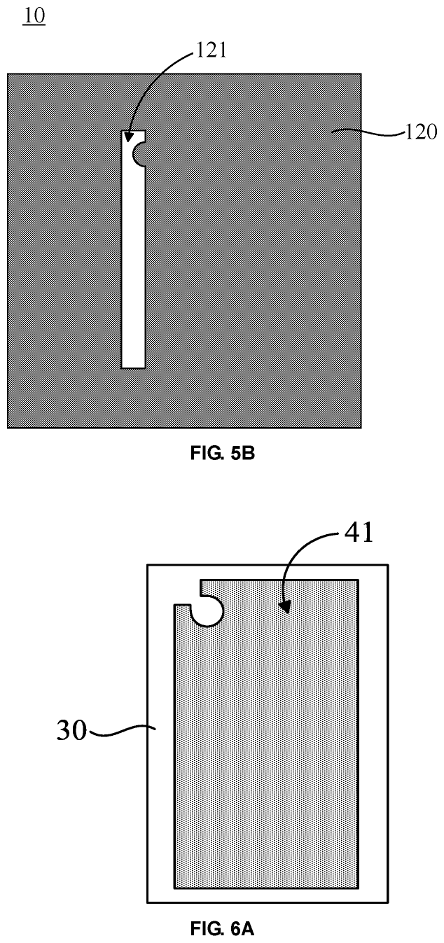

Of course, the only requirement of the shapes of the first open area 111 of the first mask plate 110 and the second open area 121 of the second mask plate 120 is that they are complementary and form the non-transparent region 211 of the display area 21 as shown in FIG. 2 after they are combined together. It may not be limited to the shape shown in FIG. 3A and FIG. 3B, and may have the shapes as shown in FIG. 4A and FIG. 4B, and FIG. 5A and FIG. 5B. Of course, the first mask plate 110 and the second mask plate 120 may further have a first frame 112 and a second frame 122, respectively.

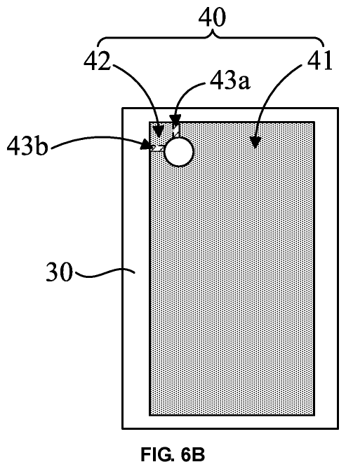

Hereinafter, the mask assembly 10 shown in FIG. 3A and FIG. 3B is taken as an example to illustrate the film layer manufacturing process of the display panel 2 as shown in FIG. 2. The first mask plate 110 of the mask assembly 10 as shown in FIG. 3A is used as a shielding layer, and is used for evaporation coating of a material on a film formation substrate 30 to obtain a first partial film layer 41 as shown in FIG. 6A; then, the second mask 120 of the mask assembly 10 as shown in FIG. 3B is used as a shielding layer, and is used for evaporation coating of the material on the film formation substrate to obtain a second partial film layer 42. The first partial film layer 41 and the second partial film layer 42 are in the same layer, as shown in FIG. 6B.

The first open area 111 is complementary to the second open area 121 and may constitute the non-transparent region 211 (i.e., the remaining area of the display area 21 after the transparent region 210 is removed) as shown in FIG. 2. Therefore, the obtained first partial film layer 41 and second partial film layer 42 shown in FIG. 6B may completely cover the non-transparent region 211 (i.e., the remaining area of the display area 21 after the transparent region 210 is removed) shown in FIG. 2. Moreover, since the vertical projection of the first opening region 111 of the first mask plate 110 and the second opening region 121 of the second mask plate 120 have overlapping portions (131a, 131b in FIG. 3A), so the first portion of the first partial film layer 41 and the second partial film layer 42 have overlapping portions (43a, 43b in FIG. 6B). Thus, with the mask assembly 10 of the present invention, a film layer 40 that completely covers the display area 21 of the display panel 2 without the transparent region 210 as shown in FIG. 6B and FIG. 2 can be obtained. The film layer 40 may be a cathode layer or a thin film encapsulating functional layer, and those skilled in the art should know that a complete thin film transistor and emissive layer structure or any other known functional layer have been formed on the film formation substrate 30.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present disclosure in any way.

### INDUSTRIAL APPLICABILITY

The main body of the present invention can be manufactured and used in the industry, and has industrial applicability.

What is claimed is:

1. A mask assembly, used for forming a film layer having a display area which comprises at least one transparent region and at least one non-transparent region, wherein the at least one transparent region is a closed graph, and a boundary of the at least one transparent region is independent from a boundary of the display area, the mask assembly comprising:
two mask plates, each mask plate having an opening area;
wherein the opening areas of the two mask plates are complementary in shape, and the at least one non-transparent region of the display area is formed by the opening areas after combining the opening areas together;
wherein the shapes of the opening areas of the two mask plates have an overlapped part, and
wherein a total area of the opening areas of the two mask plates is larger than an area of the at least one non-transparent region of the display area.

2. The mask assembly according to claim 1, wherein each of the two mask plates comprises a frame.

3. A mask assembly, used for forming a film layer having a display area, the display area comprising at least one transparent region and at least one non-transparent region, the mask assembly comprising:
two mask plates, each mask plate having an opening area;
wherein the opening areas of the two mask plates are complementary in shape, and the at least one non-transparent region of the display area are formed by the two opening areas after combining the two opening areas together; and
wherein the shapes of the opening areas of the mask plates have an overlapped part.

4. The mask assembly according to claim 3, wherein the at least one transparent region is a closed graph, and a boundary of the transparent area is independent from a boundary of the display area.

5. The mask assembly according to claim 3, wherein a total area of the opening areas of the mask plates is larger than an area of the at least one non-transparent region of the display area.

6. The mask assembly according to claim 3, wherein each mask plate comprises a frame.

7. The mask assembly according to claim 3, wherein the mask assembly comprises two mask plates.

8. A method for manufacturing a film layer, which uses the mask assembly according to claim 1, wherein a same material is evaporated through each of the mask plates functioning as a shield layer to form an evaporation coating film layer having the display area with the at least one transparent region.

9. The method according to claim 8, wherein the at least one transparent region is a closed graph, and a boundary of the transparent area is independent from a boundary of the display area.

10. The method according to claim 8, wherein the evaporation coating film layer is a cathode layer or a thin film encapsulation functional layer.
